(19) United States
(12) Patent Application Publication
(10) Pub. No.: US 2025/0185238 A1
(43) Pub. Date: Jun. 5, 2025

(54) SEMICONDUCTOR DEVICE

(71) Applicant: Samsung Electronics Co., Ltd., Suwon-si (KR)

(72) Inventors: Sunghoon BAE, Suwon-si (KR); Seungbo KO, Suwon-si (KR); Hyungmin KO, Suwon-si (KR); Euna KIM, Suwon-si (KR)

(73) Assignee: Samsung Electronics Co., Ltd., Suwon-si (KR)

(21) Appl. No.: 18/818,778

(22) Filed: Aug. 29, 2024

(30) Foreign Application Priority Data
Nov. 30, 2023 (KR) 10-2023-0170805
Feb. 23, 2024 (KR) 10-2024-0026813

(51) Int. Cl. H10B 12/00; H01L 29/06; H01L 29/423; H01L 29/49; H01L 29/51

(52) U.S. Cl. CPC H10B 12/50; H10B 12/482; H10B 12/488; H10D 62/102; H10D 64/518; H10D 64/667; H10D 64/693

(57) ABSTRACT

A semiconductor device including cell array and peripheral circuit regions; a peripheral gate structure including a peripheral gate electrode on a peripheral gate dielectric, peripheral source/drains on sides of the gate electrode, and a peripheral gate capping pattern on the peripheral gate electrode; a first peripheral interlayer insulating layer on sides of the peripheral gate structure; peripheral interconnections on the first peripheral interlayer insulating layer and the peripheral gate structure; an insulating pattern layer on the peripheral interconnections; a connection structure including a pad pattern, and a first peripheral contact plug penetrating the insulating pattern layer and electrically connecting the peripheral interconnections to the pad pattern; and a guard ring structure surrounding the cell array region between the cell array and the peripheral circuit regions. A portion of a guard ring of the guard ring structure is at a same level as a portion of the first peripheral contact plug.

### CROSS-REFERENCE TO RELATED APPLICATION(S)

This application claims benefit of priority to Korean Patent Application No. 10-2023-0170805 filed on Nov. 30, 2023 in the Korean Intellectual Property Office and Korean Patent Application No. 10-2024-0026813 filed on Feb. 23, 2024 in the Korean Intellectual Property Office, the disclosures of each of which are incorporated herein by reference in their entirety.

### BACKGROUND

Example embodiments of the present disclosure relate to semiconductor devices.

As demand for high performance, high speed, and/or multifunctionality of semiconductor devices has increased, demand for integration density of a semiconductor device has increased. In manufacturing a semiconductor device in response to the trend for high integration density of a semiconductor device, research to reduce complexity of a circuit in a peripheral circuit region has continued.

### SUMMARY

Example embodiments of the inventive concepts provide a semiconductor device having improved reliability.

Some example embodiments of the inventive concepts provide a semiconductor device that includes a substrate including a cell array region and a peripheral circuit region; a peripheral gate structure on the peripheral circuit region of the substrate, the peripheral gate structure including a peripheral gate dielectric layer, a peripheral gate electrode on the peripheral gate dielectric layer, peripheral source/drains on both sides of the peripheral gate electrode, and a peripheral gate capping pattern on the peripheral gate electrode; a first peripheral interlayer insulating layer having at least a portion on a side surface of the peripheral gate structure; peripheral interconnections on the first peripheral interlayer insulating layer and the peripheral gate structure; an insulating pattern layer on the peripheral interconnections; a connection structure including a pad pattern and a first peripheral contact plug, the pad pattern being on the insulating pattern layer, and the first peripheral contact plug penetrating the insulating pattern layer and electrically connecting the pad pattern to a peripheral interconnection from among the peripheral interconnections; and a guard ring structure including a guard ring, the guard ring structure surrounding the cell array region between the cell array region and the peripheral circuit region of the substrate. At least a portion of the guard ring of the guard ring structure is at a same level as at least a portion of the first peripheral contact plug of the connection structure.

Some example embodiments of the inventive concepts further provide a semiconductor device that includes a substrate including a cell array region and a peripheral circuit region; a conductive region in the cell array region; a peripheral gate structure on the peripheral circuit region of the substrate, the peripheral gate structure including a peripheral gate dielectric layer, a peripheral gate electrode on the peripheral gate dielectric layer, peripheral source/drains on both sides of the peripheral gate electrode, and a peripheral gate capping pattern on the peripheral gate electrode; a first peripheral interlayer insulating layer having at least a portion on a side surface of the peripheral gate structure; peripheral interconnections on the first peripheral interlayer insulating layer and the peripheral gate structure; an insulating pattern layer on the peripheral interconnections; a stopper layer on the conductive region on the cell array region, and the stopper layer being between the peripheral interconnections and the insulating pattern layer on the peripheral circuit region; a guard ring structure including a guard ring, the guard ring structure surrounding the cell array region, and the guard ring structure having a lower region penetrating the stopper layer at a portion of the stopper layer between the cell array region and the peripheral circuit region of the substrate; and a connection structure on the peripheral circuit region of the substrate, the connection structure including a pad pattern and a first peripheral contact plug, the pad pattern being on the insulating pattern layer, and the first peripheral contact plug penetrating the insulating pattern layer and the stopper layer and electrically connecting the pad pattern to a peripheral interconnection from among the peripheral interconnections.

Some example embodiments of the inventive concepts still further provide a semiconductor device that includes a substrate including a cell array region and a peripheral circuit region; a memory structure including a wordline, a bitline, and a data storage structure on the cell array region; a peripheral gate structure on the peripheral circuit region of the substrate, the peripheral gate structure including a peripheral gate dielectric layer, a peripheral gate electrode on the peripheral gate dielectric layer, peripheral source/drains on both sides of the peripheral gate electrode, and a peripheral gate capping pattern on the peripheral gate electrode; a first peripheral interlayer insulating layer having at least a portion on a side surface of the peripheral gate structure; peripheral interconnections on the first peripheral interlayer insulating layer and the peripheral gate structure; an insulating pattern layer on the peripheral interconnections; a pad pattern on the insulating pattern layer; a first peripheral contact plug penetrating the insulating pattern layer and electrically connecting the pad pattern to a peripheral interconnection from among the peripheral interconnections; an insulating liner covering the insulating pattern layer and the pad pattern; a second peripheral interlayer insulating layer on the insulating liner; a second peripheral contact plug penetrating the second peripheral interlayer insulating layer and the insulating liner, the second peripheral contact plug being electrically connected to the pad pattern; a guard ring surrounding the cell array region between the cell array region and the peripheral circuit region of the substrate; and a dummy guard pattern on the guard ring and extending in a horizontal direction toward the peripheral circuit region. The wordline and the bitline are at a level lower than a level of the guard ring. The data storage structure includes a first electrode structure, a second electrode structure and a dielectric layer between the first electrode structure and the second electrode structure. At least one of the first and second electrode structures includes a lower surface at a level lower than a level of an upper surface of the guard ring, and an upper surface at a level higher than the level of the upper surface of the guard ring.

### BRIEF DESCRIPTION OF DRAWINGS

The above and other aspects, features, and advantages of the inventive concepts will be more clearly understood from the following detailed description, taken in combination with the accompanying drawings, in which:

FIG. 1 is a plan diagram illustrating a semiconductor device according to some example embodiments of the inventive concepts;

FIGS. 2A and 2B are enlarged diagrams illustrating a portion of a semiconductor device according to some example embodiments of the inventive concepts, viewed from the side;

FIGS. 3A and 3B are cross-sectional diagrams illustrating a semiconductor device according to some example embodiments of the inventive concepts, viewed from the above;

FIG. 4 are enlarged diagrams illustrating a portion of a semiconductor device according to some example embodiments of the inventive concepts;

FIGS. 5A, 5B and 5C are enlarged diagrams illustrating a portion of a semiconductor device according to some example embodiments of the inventive concepts;

FIGS. 6A, 6B and 6C are enlarged diagrams illustrating a portion of a semiconductor device according to some example embodiments of the inventive concepts; and

FIGS. 7, 8, 9, 10, 11, 12, 13, 14 and 15 are cross-sectional diagrams illustrating a method of manufacturing a semiconductor device according to some example embodiments of the inventive concepts.

### DETAILED DESCRIPTION

Hereinafter, embodiments of the inventive concepts will be described as follows with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

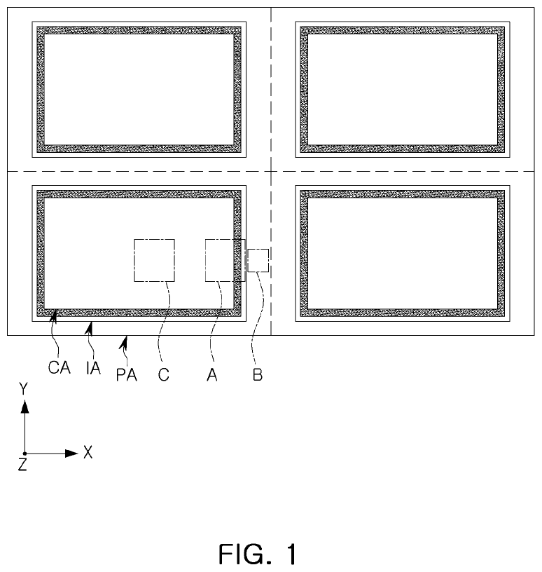

FIG. 1 is a plan diagram illustrating a semiconductor device 100 according to some example embodiments.

Referring to FIG. 1, a semiconductor device 100 according to some example embodiments may include a cell region CA and a peripheral circuit region PA. The peripheral circuit region PA may be disposed to surround the cell region CA. The cell region CA may refer to a region in which a memory cell of a dynamic random access memory (DRAM) device is disposed, and in the peripheral circuit region PA, wordline drivers, sense amplifiers, row and column decoders and control circuits may be disposed. The semiconductor device according to some example embodiments may further include an interface region IA disposed between the cell region CA and the peripheral circuit region PA. An interface region IA may electrically connect the cell region CA to the peripheral circuit region PA. The semiconductor device according to some example embodiments may include a guard ring structure GRS disposed to surround the cell region CA on the interface region IA.

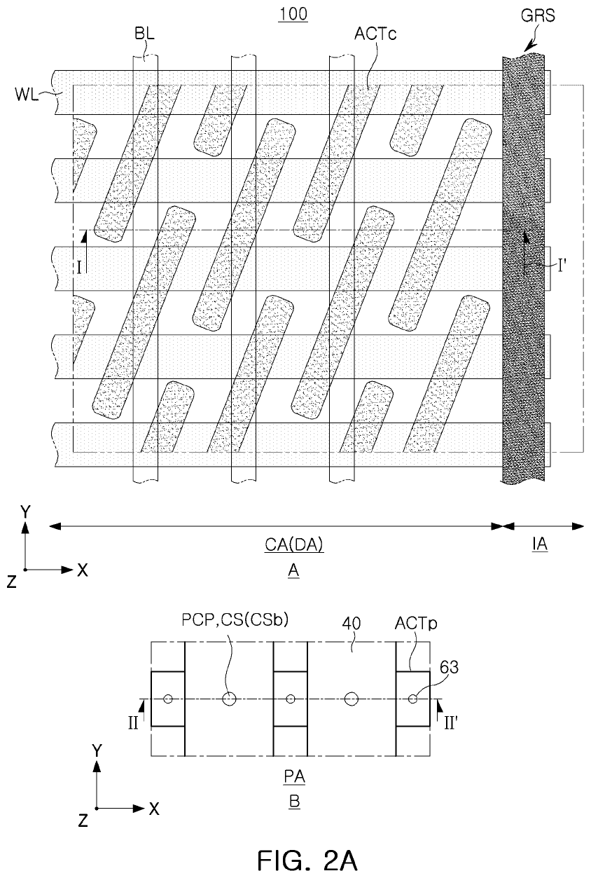

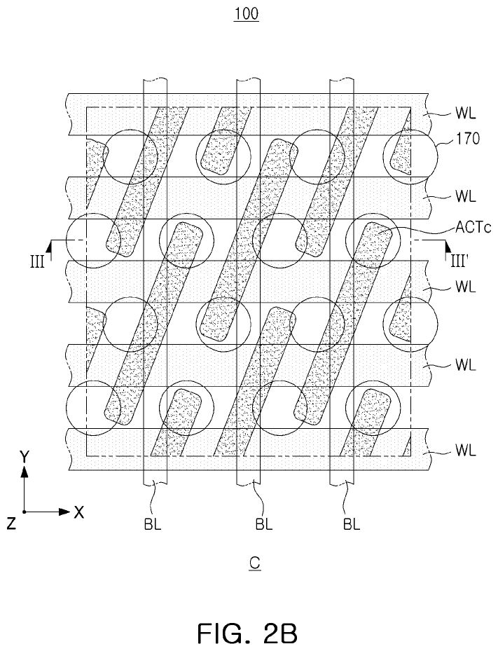

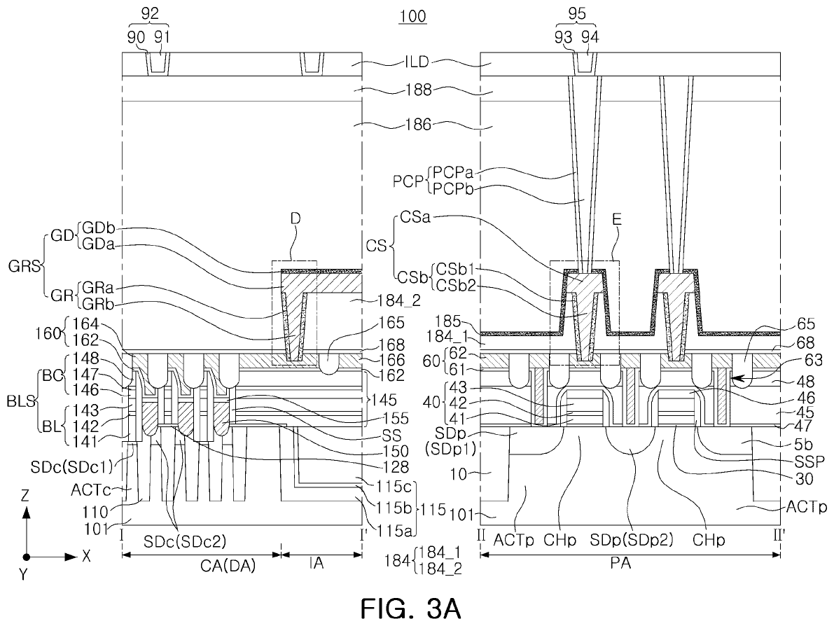

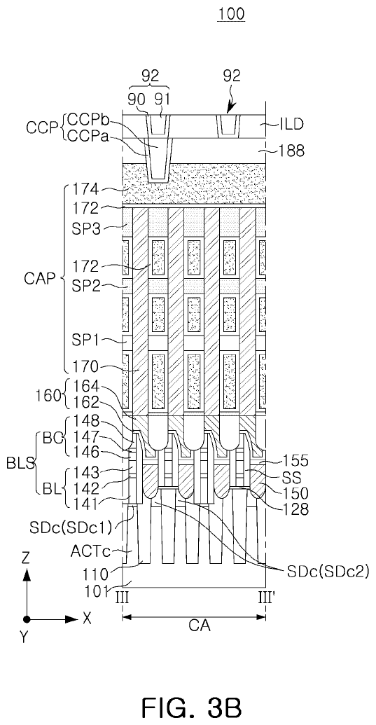

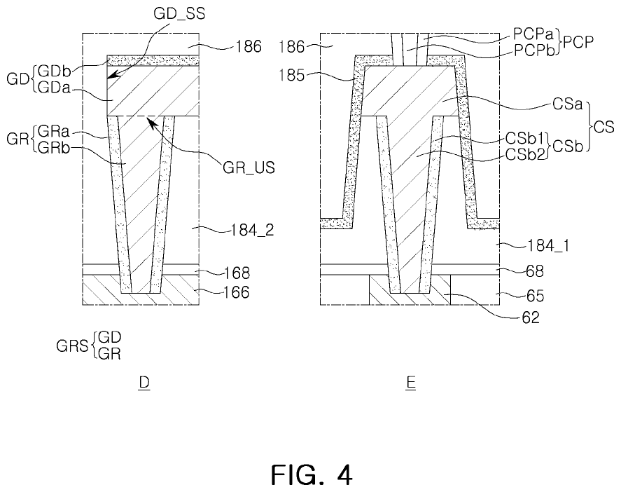

FIGS. 2A and 2B are enlarged diagrams illustrating a semiconductor device 100 according to some example embodiments. FIG. 2A is an enlarged diagram illustrating regions “A” and “B,” and FIG. 2B is an enlarged diagram illustrating region “C.” FIGS. 3A and 3B are vertical cross-sectional diagrams illustrating a semiconductor device 100 according to some example embodiments. FIG. 3A is a vertical cross-sectional diagram illustrating the semiconductor device illustrated in FIG. 2A taken along lines I-I′ and II-II′. FIG. 3B is a vertical cross-sectional diagram illustrating the semiconductor device illustrated in FIG. 2B taken along line III-III′. FIG. 4 is an enlarged diagram illustrating a semiconductor device according to some example embodiments. FIG. 4 is an enlarged diagram illustrating regions “D” and “E” in FIG. 3A.

Referring to FIGS. 2A, 2B, 3A, and 3B, the semiconductor device 100 may include a substrate 101 including cell active regions ACTc disposed on the cell region CA, a device isolation layer 110 defining the cell active regions ACTc in the substrate 101, a bitline structure BLS disposed on the substrate 101 and including a bitline BL, and a data storage structure CAP on the bitline structure BLS. The data storage structure CAP may store data, and may be configured as a capacitor structure of DRAM, for example. According to some example embodiments, a partial region of the cell region CA may be referred to as a dummy pattern region DA. The dummy pattern region DA may not include the data storage structure CAP and may be in contact with the interface region IA of the cell region CA.

In the cell region CA, the semiconductor device 100 may further include a lower conductive pattern 150 on the cell active region ACTc, an upper conductive pattern 160 on the lower conductive pattern 150, and an insulating pattern 165 penetrating the upper conductive pattern 160.

Although not illustrated, the semiconductor device 100 may further include a wordline WL disposed in the cell region CA and buried in the substrate 101.

The semiconductor device 100 may include, for example, a cell array of dynamic random access memory (DRAM). For example, the bitline BL may be connected to the first cell impurity region SDc1 of the cell active region ACTc, and the second cell impurity region SDc2 of the cell active region ACTc may be electrically connected to the data storage structure CAP on the upper conductive pattern 160 through the lower and upper conductive patterns 150 and 160. The bitline BL may be disposed on a level lower than a level of the guard ring structure GRS. Although not illustrated, the wordline WL buried in the substrate 101 may also be disposed on a level lower than a level of the guard ring structure GRS.

Data storage structure CAP may be configured as a capacitor which may store data in a memory such as a DRAM. The data storage structure CAP may be electrically connected to conductive regions 150 and 160, for example, on the lower structure including lower and upper conductive patterns 150 and 160. Here, the lower structure may include the substrate 101, the wordline, and the bitline structure BLS.

The data storage structure CAP may include first electrode structures 170, a dielectric layer 172 on the first electrode structures 170, and a second electrode structure 174 on the dielectric layer 172. The data storage structure CAP may further include supporter layers SP1, SP2, and SP3. The first electrode structures 170 may be lower electrodes, and the second electrode structures 174 may be upper electrodes.

Referring to FIGS. 3A and 3B together, at least one of the first electrode structures 170 and the second electrode structures 174 may have a lower surface disposed on a level lower than a level of an upper surface of the guard ring structure GRS, and an upper surface disposed on a level higher than a level of an upper surface of the guard ring structure GRS. For example, each of the first electrode structures 170 and second electrode structures 174 may have a lower surface disposed on a level lower than a level of the upper surface of the guard ring GR and an upper surface disposed on a level higher than a level of the upper surface of the guard ring GR.

The substrate 101 may include a semiconductor material, for example, a group IV semiconductor, a group III-V compound semiconductor, or a group II-VI compound semiconductor. For example, group IV semiconductors may include silicon, germanium, or silicon-germanium. The substrate 101 may further include impurities. The substrate 101 may be configured as a silicon substrate, a silicon-on-insulator (SOI) substrate, a germanium substrate, a germanium-on-insulator (GOI) substrate, a silicon-germanium substrate, or a substrate including an epitaxial layer.

Cell active regions ACTc may be defined in the substrate 101 by the device isolation layer 110. The cell active region ACTc may have first and second cell impurity regions SDc1 and SDc2 at a desired (and/or alternatively predetermined) depth from an upper surface of the substrate 101. The first and second cell impurity regions SDc1, SDc2 may be spaced apart from each other. The first and second cell impurity regions SDc1 and SDc2 may be provided as a source/drain region of the transistor configured by the wordline. The source region and the drain region may be formed by the first and second cell impurity regions SDc1 and SDc2 by doping or ion implantation of substantially the same impurities, and may be referred to interchangeably depending on a circuit configuration of a finally formed transistor. The impurities may include impurities having a conductivity-type opposite to that of the substrate 101. In some example embodiments, depths of the first and second cell impurity regions SDc1 and SDc2 in the source region and the drain region may be different.

A device isolation layer 110 may be formed by a shallow trench isolation (STI) process. The device isolation layer 110 may surround the cell active regions ACTc and may electrically isolate the regions from each other. The device isolation layer 110 may be formed of an insulating material, for example, silicon oxide, silicon nitride, or a combination thereof.

Although not illustrated, wordline WL may be disposed to extend in the first direction X across the cell active region ACTc. For example, a pair of adjacent wordlines may be disposed to cross the cell active region ACTc. A wordline may be included in a gate of a buried channel array transistor (BCAT), but some example embodiments thereof are not limited thereto.

The bitline structure BLS may extend perpendicularly to a wordline in one direction, for example, in the second direction Y. The bitline structure BLS may include a bitline BL and a bitline capping pattern BC on the bitline BL.

The bitline BL may include a first conductive pattern 141, a second conductive pattern 142, and a third conductive pattern 143 stacked in order. The bitline capping pattern BC may be disposed on the third conductive pattern 143. A buffer insulating layer 128 may be disposed between the first conductive pattern 141 and the substrate 101, and a portion (hereinafter referred to as bitline contact pattern DC) of the first conductive pattern 141 may be in contact with the first cell impurity region SDc1 of the cell active region ACTc. The bitline BL may be electrically connected to a first cell impurity region SDc1 through the bitline contact pattern DC. A lower surface of the bitline contact pattern DC may be disposed on a level lower than a level of an upper surface of the substrate 101, and may be disposed on a level higher than a level of an upper surface of the wordline. In some example embodiments, the bitline contact pattern DC may be formed in the substrate 101 and may be locally disposed in a bitline contact hole exposing the first cell impurity region SDc1.

The first conductive pattern 141 may include a semiconductor material such as polycrystalline silicon. The first conductive pattern 141 may be in direct contact with the first cell impurity region SDc1. The second conductive pattern 142 may include a metal-semiconductor compound. For example, the metal-semiconductor compound may be a layer siliciding a portion of the first conductive pattern 141. For example, the metal-semiconductor compound may include cobalt silicide (CoSi), titanium silicide (TiSi), nickel silicide (NiSi), tungsten silicide (WSi), or other metal silicide. The third conductive pattern 143 may include a metal material such as titanium (Ti), tantalum (Ta), tungsten (W), and aluminum (Al). The number of conductive patterns included in the bitline BL, the type of material thereof, and/or the stacking order thereof may be varied in some example embodiments.

The bitline capping pattern BC may include a first capping pattern 146, a second capping pattern 147, and a third capping pattern 148 stacked in order on the third conductive pattern 143. Each of the first to third capping patterns 146, 147, and 148 may include an insulating material, for example, a silicon nitride film. The first to third capping patterns 146, 147, and 148 may be formed of different materials, and even when the first to third capping patterns 146, 147, and 148 include the same material, boundaries may be distinct due to differences in physical properties. A thickness of the second capping pattern 147 may be smaller than a thickness of each of the first capping pattern 146 and the third capping pattern 148. The number of capping patterns included in the bitline capping pattern BC and/or type of material thereof may be varied in some example embodiments.

Although not illustrated, spacer structures may be disposed on both sidewalls of each bitline structure BLS. The spacer structures may extend in one direction, for example, the Y-direction, on both sidewalls of each bitline structure BLS. The spacer structures may be disposed between the bitline structure BLS and the lower conductive pattern 150. The spacer structures may be disposed to extend along sidewalls of the bitline BL and sidewalls of the bitline capping pattern BC. A pair of spacer structures disposed on both sides of one bitline structure BLS may have an asymmetric shape with respect to the bitline structure BLS. Each of the spacer structures may include a plurality of spacer layers, and may further include an air spacer in some example embodiments.

The lower conductive pattern 150 may be connected to one region of the cell active region ACTc, for example, the second cell impurity region SDc2. The lower conductive pattern 150 may be disposed between the bitlines BL. The lower conductive pattern 150 may penetrate a buffer insulating layer 128 and may be connected to the second cell impurity region SDc2 of the cell active region ACTc. The lower conductive pattern 150 may be in direct contact with the second cell impurity region SDc2. A lower surface of the lower conductive pattern 150 may be disposed on a level lower than a level of an upper surface of the substrate 101, and may be disposed on a level higher than a level of a lower surface of the bitline contact pattern DC. The lower conductive pattern 150 may be insulated from the bitline contact pattern DC by the spacer structure SS. The lower conductive pattern 150 may be formed of a conductive material, such as at least one of polycrystalline silicon (Si), titanium (Ti), titanium nitride (TiN), tantalum (Ta), tantalum nitride (TaN), tungsten (W), tungsten nitride (WN), and aluminum (Al). In example embodiments, the lower conductive pattern 150 may include a plurality of layers.

The metal-semiconductor compound layer 155 may be disposed between the lower conductive pattern 150 and the upper conductive pattern 160. For example, when the lower conductive pattern 150 may include a semiconductor material, the metal-semiconductor compound layer 155 may be obtained by siliciding a portion of the lower conductive pattern 150. The metal-semiconductor compound layer 155 may include, for example, cobalt silicide (CoSi), titanium silicide (TiSi), nickel silicide (NiSi), tungsten silicide (WSi), or other metal silicide. In some example embodiments, the metal-semiconductor compound layer 155 may not be provided.

The upper conductive pattern 160 may be disposed on the lower conductive pattern 150. The upper conductive pattern 160 may extend to a region between the spacer structures SS and may cover an upper surface of the metal-semiconductor compound layer 155. The upper conductive pattern 160 may include a barrier layer 162 and a conductive layer 164. The barrier layer 162 may cover a lower surface and side surfaces of the conductive layer 164. The barrier layer 162 may include metal nitride, such as at least one of titanium nitride (TiN), tantalum nitride (TaN), and tungsten nitride (WN). The conductive layer 164 may include a conductive material, such as at least one of polycrystalline silicon (Si), titanium (Ti), tantalum (Ta), tungsten (W), ruthenium (Ru), copper (Cu), molybdenum (Mo), and platinum (Pt), nickel (Ni), cobalt (Co), aluminum (Al), titanium nitride (TiN), tantalum nitride (TaN), and tungsten nitride (WN).

The insulating patterns 165 may be disposed to penetrate the upper conductive pattern 160. The upper conductive pattern 160 may be isolated into a plurality of portions by the insulating patterns 165. The insulating patterns 165 may include at least one of an insulating material, for example, silicon oxide, silicon nitride, and silicon oxynitride.

The etch stop layer 168 (or “stopper layer”) may cover the insulating patterns 165 between the first electrode structures 170. The etch stop layer 168 may be in contact with a lower region of side surfaces of the first electrode structures 170. The etch stop layer 168 may be disposed below the supporter layers SP1, SP2, and SP3. An upper surface of the etch stop layer 168 may include a portion in direct contact with the dielectric layer 172. The etch stop layer 168 may include, for example at least one of silicon nitride, and silicon oxynitride. The etch stop layer 168 may further extend from cell region CA to the peripheral circuit region PA (see FIG. 3A). For example, the etch stop layer 168 may extend in the horizontal direction (X-direction) from the cell region CA (or “dummy pattern region DA”) toward the peripheral circuit region PA. Here, the etch stop layer 168 may have the same level on the cell region CA, the interface region IA, and the peripheral circuit region PA.

The first electrode structures 170 may be disposed on the upper conductive patterns 160. The first electrode structures 170 may penetrate the etch stop layer 168 and may be in contact with the upper conductive patterns 160. The first electrode structures 170 may have a pillar shape, but some example embodiments thereof are not limited thereto. Each of the first electrode structures 170 may include at least one of niobium nitride (NbN), niobium oxide (NbOx), polycrystalline silicon (Si), iridium (Ir), titanium (Ti), titanium nitride (TiN), titanium silicide nitride (TiSiN), tantalum (Ta), tantalum nitride (TaN)), tungsten (W), tungsten nitride (WN), and aluminum (Al), or combinations thereof, metal nitride, and metal compound.

The dielectric layer 172 may cover a side surface and an upper surface of each of the first electrode structures 170 on a surface of the first electrode structures 170. The dielectric layer 172 may be disposed between the first electrode structures 170 and the second electrode structures 174. The dielectric layer 172 may cover upper and lower surfaces of the support layers SP1, SP2, and SP3. The dielectric layer 172 may cover an upper surface of the etch stop layer 168.

The dielectric layer 172 may include a high dielectric material, silicon oxide, silicon nitride, or a combination thereof. However, in some example embodiments, the dielectric layer 172 may include at least one of fluorine (F)-doped titanium (Ti), tantalum (Ta), hafnium (Hf), aluminum (Al), zirconium (Zr), and lanthanum (La), or oxide, nitride, silicide, oxynitride, or silicified oxynitride, including combinations thereof.

The second electrode structure 174 may be disposed on the dielectric layer 172. The second electrode structure 174 may fill a space between the plurality of first electrode structures 170 and a space between the supporter layers SP1, SP2, and SP3. In some example embodiments, the dielectric layer 172 and the second electrode structure 174 may further extend into the interface region IA. The second electrode structure 174 may include a conductive material.

The second electrode structure 174 may be formed of a single layer or a plurality of layers. In some example embodiments, the second electrode structure 174 may be in direct contact with the dielectric layer 172 and may include a first material layer formed along the dielectric layer 172 and a second material layer covering the first material layer. The first material layer may include a doped semiconductor, a metal, a conductive metal nitride, a metal-semiconductor compound, a conductive metal oxide, or a combination thereof. The second material layer may include a silicon material or a silicon-germanium material. For example, the second material layer may include a doped silicon material or a doped silicon-germanium material.

The supporter layers SP1, SP2, and SP3 may include a first supporter layer SP1, a second supporter layer SP2 on the first supporter layer SP1, and a third supporter layer SP3 on the second supporter layer SP2. The supporter layers SP1, SP2, and SP3 may be spaced apart from the substrate 101 in a direction perpendicular to an upper surface of the substrate 101. The supporter layers SP1, SP2, and SP3 may be in contact with the first electrode structures 170 and may extend in a direction parallel to an upper surface of the substrate 101.

The supporter layers SP1, SP2, and SP3 may support the first electrode structures 170 having a high aspect ratio. Each of the support layers SP1, SP2, and SP3 may include, for example, at least one of silicon nitride, silicon oxynitride, or similar materials. The number of the supporter layers SP1, SP2, and SP3, a thickness thereof, and/or arrangement relationship thereof are not limited to the illustrated examples and may be varied in example embodiments.

Referring to FIG. 2B, the first electrode structures 170 may be arranged in a regular pattern in the plan diagram. In some example embodiments, the first electrode structures 170 may be separated at a desired (and/or alternatively predetermined) distance in the first direction X and disposed in a zigzag pattern in the second direction Y. The arrangement of the first electrode structures 170 is not limited thereto.

Referring to FIGS. 3A and 3B, the semiconductor device 100 may further include second electrode structures 174 on the cell region CA (see FIG. 3B), and may further include a guard ring structure GRS on the interface region IA, a lower interlayer insulating layer 186 disposed on the connection structure CS on the peripheral circuit region PA, and an upper interlayer insulating layer 188 on the lower interlayer insulating layer 186 (see FIG. 3A). Although not illustrated, the lower interlayer insulating layer 186 may be in contact with a side surface of the second electrode structures 174. The lower interlayer insulating layer 186 may also be in contact with the dielectric layer 172. The upper interlayer insulating layer 188 may be disposed on the lower interlayer insulating layer 186. In some example embodiments, an interlayer insulating pattern layer 184 including an interlayer insulating pattern layer 184_2 covering one side surface of the guard ring structure GRS on the interface region IA and an interlayer insulating pattern layer 184_1 covering the side surface of the connection structure CS on the peripheral circuit region PA may be further included.

The interlayer insulating pattern layer 184, the lower interlayer insulating layer 186, and the upper interlayer insulating layer 188 may include silicon oxide, silicon nitride, silicon oxynitride, or a combination thereof. In some example embodiments, the interlayer insulating pattern layer 184, the lower interlayer insulating layer 186, and the upper interlayer insulating layer 188 may include silicon oxide. Even though the lower interlayer insulating layer 186 may include the same material as that of the upper interlayer insulating layer 188, a boundary therebetween may be distinct. An upper surface of the upper interlayer insulating layer 188 may be flat, for example, parallel to an upper surface of the substrate 101.

The semiconductor device 100 may further include a cell contact plug CCP, an interlayer insulating layer ILD and a plurality of upper contact plugs 92. The cell contact plug CCP may penetrate the upper interlayer insulating layer 188 and may be connected to the data storage structure CAP. For example, the cell contact plug CCP may penetrate the upper interlayer insulating layer 188 and may be connected to the second electrode structure 174. A lower surface of the cell contact plug CCP may be disposed on a level lower than a level of an upper surface of the second electrode structure 174. An upper surface of the cell contact plug CCP may be coplanar with an upper surface of the upper interlayer insulating layer 188. The cell contact plug CCP may include a barrier layer CCPa and a conductive layer CCPb on the barrier layer CCPa. A side surface of the cell contact plug CCP may be in contact with the lower interlayer insulating layer 186 and the upper interlayer insulating layer 188.

The interlayer insulating layer ILD may be disposed on the upper interlayer insulating layer 188. The interlayer insulating layer ILD may cover the cell contact plug CCP and the upper interlayer insulating layer 188. The interlayer insulating layer ILD may include silicon oxide.

The plurality of upper contact plugs 92 may penetrate the interlayer insulating layer ILD, and at least one of the plurality of upper contact plugs 92 may be connected to the cell contact plug CCP. The plurality of upper contact plugs 92 may include a barrier layer 90 and a conductive layer 91 on the barrier layer 90, respectively. Lower surfaces of the plurality of upper contact plugs 92 may be flat, for example, parallel to an upper surface of the substrate 101. The lower surfaces of the plurality of upper contact plugs 92 may be disposed on the same level.

The barrier layer CCPa and the barrier layer 90 may include a metal nitride such as titanium nitride (TiN). The conductive layer CCPb and the conductive layer 91 may include a conductive material such as tungsten (W) and tungsten nitride (WN).

In the peripheral circuit region PA, the semiconductor device 100 may include a device isolation layer 10 defining the peripheral active region ACTp. The device isolation layer 10 may be configured as an insulating layer extending downwardly from an upper surface of the substrate 101. In the upper region of the peripheral active region ACTp, peripheral source/drain regions SDp and a peripheral channel region CHp may be disposed. The peripheral source/drain regions SDp may include the first peripheral source/drain region SDp1 and the second peripheral source/drain region SDp2, and the first peripheral source/drain region SDp1 and the second peripheral source/drain region SDp2 may be spaced apart from each other with the peripheral gate structure 40 therebetween. The peripheral channel region CHp may be disposed between the peripheral source/drain regions SDp.

The device isolation layer 10 may include silicon oxide, silicon nitride, silicon oxynitride, or a combination thereof, and may be configured as a single layer or a plurality of layers. The peripheral source/drain regions SDp may be provided as a source/drain region of a transistor formed by the peripheral gate structure 40. The peripheral source/drain regions SDp may include impurities having a conductivity-type opposite to that of the substrate 101.

The semiconductor device 100 may further include a peripheral gate dielectric layer 30 and a peripheral gate structure 40 disposed on the substrate 101 in the peripheral circuit region PA. The peripheral gate structure 40 may have a structure similar to that of the bitline BL and may be formed of a material similar to that of the bitline BL.

The peripheral gate structure 40 may include a first conductive pattern 41, a second conductive pattern 42, and a third conductive pattern 43 stacked in order on the peripheral gate dielectric layer 30 of the substrate 101. The peripheral gate dielectric layer 30 may include silicon oxide, silicon nitride, or a high-K material. The high-K material may refer to a dielectric material having a dielectric constant higher than that of silicon oxide. The first conductive pattern 41, the second conductive pattern 42 and the third conductive pattern 43 of the peripheral gate structure 40 may include the same material as that of the first conductive pattern 141, the second conductive pattern 142 and the third conductive pattern 143 of the bitline BL, respectively. The first peripheral capping pattern 46 may be disposed on the peripheral gate structure 40. The first peripheral capping pattern 46 may include the same material as that of the first capping pattern 146 of the bitline capping pattern BC.

The semiconductor device 100 may further include a peripheral gate spacer SSP, a second peripheral capping pattern 47, a peripheral interlayer insulating layer 45 and a third peripheral capping pattern 48 in the peripheral circuit region PA. The peripheral gate spacer SSP may cover a side surface of the peripheral gate structure 40. For example, the peripheral gate spacers SSP may be spaced apart from each other with the peripheral gate structure 40 therebetween, and may cover side surfaces of the first conductive pattern 41, the second conductive pattern 42, the third conductive pattern 43 and the first peripheral capping pattern 46.

The second peripheral capping pattern 47 may cover the substrate 101, the peripheral gate spacer SSP, and the peripheral gate structure 40, and may be formed conformally. The peripheral interlayer insulating layer 45 may partially cover the second peripheral capping pattern 47. An upper surface of the peripheral interlayer insulating layer 45 may be coplanar with an upper surface of the second peripheral capping pattern 47. The third peripheral capping pattern 48 may cover the peripheral interlayer insulating layer 45 and the second peripheral capping pattern 47.

Each of the second peripheral capping pattern 47 and the third peripheral capping pattern 48 may include the same material as that of the second capping pattern 147 and the third capping pattern 148 of the bitline capping pattern BC, respectively, and may include, for example, silicon nitride. The peripheral interlayer insulating layer 45 may include silicon oxide.

The semiconductor device 100 may further include a peripheral plug 63 and a peripheral interconnection 60 electrically connected to the peripheral source/drain region SDp in the peripheral circuit region PA. The peripheral plugs 63 may penetrate through the peripheral interlayer insulating layer 45, may be disposed adjacent to the peripheral gate structure 40 and may be in contact with the peripheral source/drain region SDp. The peripheral interconnection 60 may be disposed on the third peripheral capping pattern 48 and the peripheral plug 63 and may extend in the first direction.

The semiconductor device 100 may further include an insulating pattern 65 disposed between the peripheral interconnections 60. The insulating patterns 65 may spatially isolate the peripheral interconnections 60 and may electrically insulate the peripheral interconnections 60 from each other.

The semiconductor device 100 may further include an etch stop layer 68 disposed on the peripheral interconnections 60. The etch stop layer 68 may be formed integrally with the etch stop layer 168. For example, the etch stop layer 68 may be formed by extending the etch stop layer 168 to the peripheral circuit region PA. Accordingly, the etch stop layer 68 of the peripheral circuit region PA and the etch stop layer 168 of the cell region CA may be disposed on the same level.

Referring to FIGS. 3A and 4 together, in the peripheral circuit region PA, the semiconductor device 100 may further include an interlayer insulating pattern layer 184_1, a connection structure CS, and an insulating liner 185 disposed between the peripheral interconnections 60 and the lower interlayer insulating layer 186.

The interlayer insulating pattern layer 184_1 may be disposed on the peripheral interconnections 60 and may extend to the interface region IA. Accordingly, in the interface region IA, the interlayer insulating pattern layer 184_2 may be in contact with at least a portion of the guard ring structure GRS. The interlayer insulating pattern layer 184_2 may include silicon oxide, silicon nitride, silicon oxynitride, or a combination thereof. In some example embodiments, the interlayer insulating pattern layer 184_2 may include silicon oxide. On the peripheral circuit region PA, the interlayer insulating pattern layer 184_1 may have upper surfaces on different levels. For example, the interlayer insulating pattern layer 184_1 disposed on the peripheral gate structure 40 may have an upper surface disposed on a level higher than a level of the interlayer insulating pattern layer 184_1 not disposed on the peripheral gate structure 40. On the interface region IA, the interlayer insulating pattern layer 184_2 may have an upper surface disposed on the same level.

The connection structure CS may be disposed on the interlayer insulating pattern layer 184_1. The connection structure CS may include a pad pattern CSa and a contact plug CSb (or “first peripheral contact plug”). According to some example embodiments, a peripheral interconnection circuit including a plurality of layers may be implemented by forming a connection structure CS including a pad pattern CSa and a contact plug CSb on the peripheral interconnection 60 in the peripheral circuit region (PA). Accordingly, complexity of a circuit may be reduced, an area of the peripheral circuit region PA may be reduced, and a peripheral contact plug PCP penetrating the interlayer insulating layer 186 may be easily formed. The pad pattern CSa may be disposed on the interlayer insulating pattern layer 184_1 disposed on the peripheral gate structure 40. The contact plug CSb may penetrate the interlayer insulating pattern layer 184_1 and the etch stop layer 68 disposed on the peripheral gate structure 40. An upper region of the contact plug CSb may be configured as a region continuously continuing from a lower region of the pad pattern CSa. The lower region of the contact plug CSb may be disposed in the peripheral interconnections 60, and a lower surface of the contact plug CSb may be in contact with at least a portion of the peripheral interconnections 60. Accordingly, the contact plug CSb may electrically connect the pad pattern CSa to the peripheral interconnections 60.

The contact plug CSb may include a barrier layer CSb1 and a conductive layer CSb2 on the barrier layer CSb1. The barrier layer CSb1 may be disposed along a sidewall of the contact plug CSb, and the conductive layer CSb2 may be disposed in the contact plug CSb. The barrier layer CSb1 may include an insulating material such as silicon oxycarbide, silicon nitride, and silicon oxycarbonitride. The conductive layer CSb2 of the pad pattern CSa and the contact plug CSb may include the same conductive material. For example, the pad pattern CSa and the conductive layer CSb2 may include a conductive material such as tungsten (W) and tungsten nitride (WN). For example, the pad pattern CSa and the conductive layer CSb2 may have a continuous shape. For example, an upper region of the conductive layer CSb2 may continue from a lower region of the pad pattern CSa, and for example, a boundary surface between a lower surface of the pad pattern CSa and an upper surface of the conductive layer CSb2 may not be distinct.

The insulating liner 185 may cover at least a portion of a surface of the interlayer insulating pattern layer 184_1 and a surface of the pad pattern CSa of the connection structure CS. The insulating liner 185 may extend into the interface region IA. Accordingly, in the interface region IA, the insulating liner 185 may form a component of the guard ring structure GRS. For example, the insulating liner 185 may correspond to the second pattern GDb of the dummy guard pattern GD of the guard ring structure GRS. The insulating liner 185 may include an insulating material such as silicon oxide, silicon oxycarbide, and silicon nitride. In some example embodiments, the insulating liner 185 may include silicon nitride.

The semiconductor device 100 may further include a peripheral contact plug PCP (or “second peripheral contact plug”) and the upper contact plug 95 disposed on the connection structure CS. The peripheral contact plug PCP may penetrate the upper interlayer insulating layer 188, the lower interlayer insulating layer 186 and the insulating liner 185 and may be in contact with the pad pattern CSa. The peripheral contact plug PCP may be electrically connected to the first peripheral source/drain region SDp1 or the second peripheral source/drain region SDp2 through the pad pattern CSa, the contact plug CSb, the peripheral interconnection 60 and the peripheral plug 63. An upper surface of the peripheral contact plug PCP may be coplanar with upper surfaces of the cell contact plug CCP and the upper interlayer insulating layer 188. The peripheral contact plug PCP may include a barrier layer PCPa and a conductive layer PCPb on the barrier layer PCPa.

The upper contact plug 95 may penetrate the interlayer insulating layer ILD, and the upper contact plug 95 may be connected to the peripheral contact plug PCP. The upper contact plug 95 may include a barrier layer 93 and a conductive layer 94 on the barrier layer 93. A lower surface of the upper contact plug 95 may be flat, for example, parallel to an upper surface of the substrate 101. A lower surface of the upper contact plug 95 may be disposed on the same level as lower surfaces of the plurality of upper contact plugs 92.

The barrier layer PCPa and the barrier layer 93 may include a metal nitride such as titanium nitride (TiN). The conductive layer PCPb and the conductive layer 94 may include a conductive material such as tungsten (W) and tungsten nitride (WN).

In the interface region IA, the semiconductor device 100 may include a dummy pattern extension portion 145 including a device isolation layer 115 disposed in substrate 101 and a plurality of dummy pattern layers disposed on the substrate 101, a barrier layer 162, a dummy conductive pattern 166, and an etch stop layer 168.

The device isolation layer 115 may include a buried insulating layer 115a, an insulating liner 115b, and a gap-fill insulating layer 115c disposed in order in a desired (and/or alternatively predetermined) trench. The dummy pattern extension portion 145 may be configured as an extension portion in which the plurality of conductive patterns 141, 142, and 143 and the plurality of capping patterns 146, 147, and 148 of the dummy pattern region DA extend to the interface region IA. Similarly, each of the barrier layer 162 and the dummy conductive pattern 166 may be patterns in which the barrier layer 162 and the upper conductive pattern 164 of the dummy pattern region DA extend to the interface region IA.

In the interface region IA, the semiconductor device 100 may further include an etch stop layer 168 disposed on the dummy conductive pattern 166. As described above, the etch stop layer 168 may extend from the cell region CA to the peripheral circuit region PA, and the etch stop layer 168 may have the same level on the cell region CA, the interface region IA, and the peripheral circuit region PA.

Referring to FIGS. 3A and 4 together, in the interface region IA, the semiconductor device 100 may further include a guard ring structure GRS disposed on the etch stop layer 168 and surrounding the cell region CA. The guard ring structure GRS may include a guard ring GR and a dummy guard pattern GD disposed on the guard ring GR. According to some example embodiments, by implementing a guard ring structure GRS in the cell region CA which may be formed together with the connection structure CS in the peripheral circuit region PA, a separate process for forming the connection structure CS can be reduced.

In top plan view, the guard ring GR may have a ring shape surrounding the cell region CA (see FIG. 1), and in cross-sectional view, the guard ring GR may have a pillar shape in which a horizontal width may increase from a lower region to an upper region (see FIG. 3A). The guard ring GR may include a barrier layer GRa and a conductive layer GRb on the barrier layer GRa. The barrier layer GRa may be disposed along a sidewall of the guard ring GR, and the conductive layer GRb may be disposed in the guard ring GR. The barrier layer GRa of the guard ring GR may include the same material as that of the barrier layer CSb1 of the contact plug CSb of the connection structure CS. Similarly, the conductive layer GRb of the guard ring GR may also include the same material as that of the conductive layer CSb2 of the contact plug CSb of the connection structure CS.

The semiconductor device 100 may further include an interlayer insulating pattern layer 184_2 disposed on one side of the guard ring GR. The interlayer insulating pattern layer 184_2 in the interface region IA may be integrated with and physically connected to the interlayer insulating pattern layer 184_1 in the peripheral circuit region PA (not illustrated).

The dummy guard pattern GD may be configured as a plurality of dummy patterns disposed on the guard ring GR. The dummy guard pattern GD may extend in the horizontal direction (X-direction) toward the peripheral circuit region PA on the guard ring GR and the interlayer insulating pattern layer 184_2.

The dummy guard pattern GD may include the first pattern GDa and the second pattern GDb on the first pattern GDa. The first pattern GDa may be disposed on the upper surface of the guard ring GR and the interlayer insulating pattern layer 184_2, and may include a conductive material. For example, the first pattern GDa may include the same conductive material as that of the conductive layer GRb of the guard ring GR. For example, a boundary surface between a lower surface of the first pattern GDa and an upper surface of the conductive layer GRb may not be distinct. Also, the first pattern GDa may include the same conductive material as that of the conductive layer CSb2 of the contact plug CSb of the connection structure. The second pattern GDb may be configured as a pattern in which the insulating liner 185 of the peripheral circuit region PA extends to the interface region IA. Accordingly, the second pattern GDb may include the same insulating material as that of the insulating liner 185.

At least a portion of the guard ring structure GRS may be on the same level as at least a portion of the connection structure CS. For example, an upper surface of the guard ring GR of the guard ring structure GRS may be on substantially the same level as a level of an upper surface of the contact plug CSb of the connection structure CS. Also, an upper surface of the first pattern GDa of the dummy guard pattern GD of the guard ring structure GRS may be on substantially the same level as a level of an upper surface of the pad pattern CSa of the connection structure CS. In different view, the second pattern GDb of the dummy guard pattern GD of the guard ring structure GRS may be substantially on the same level as an upper surface of the insulating liner 185.

Referring to FIG. 4, in cross-sectional view, one side surface of the dummy guard pattern GD may have a linear shape in the vertical direction (Z-direction). Also, the one side surface of the dummy guard pattern GD may vertically overlap an edge of an upper surface of the guard ring GR.

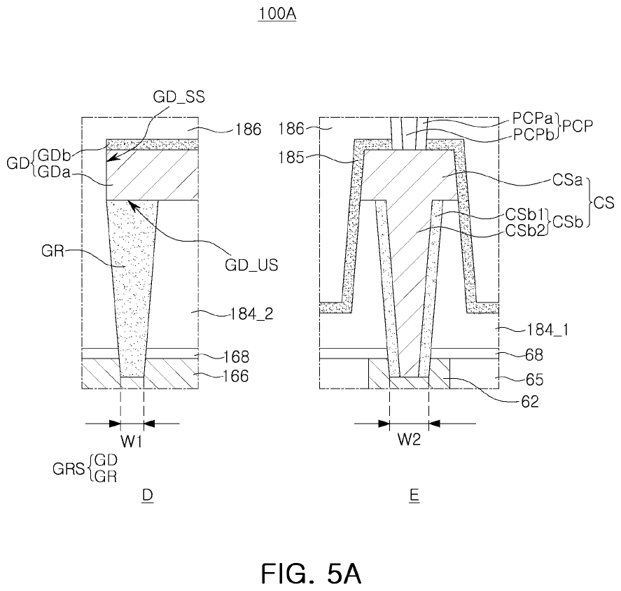

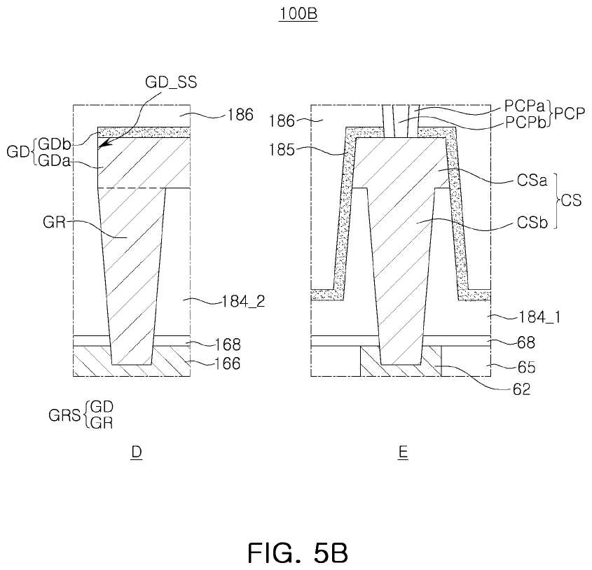

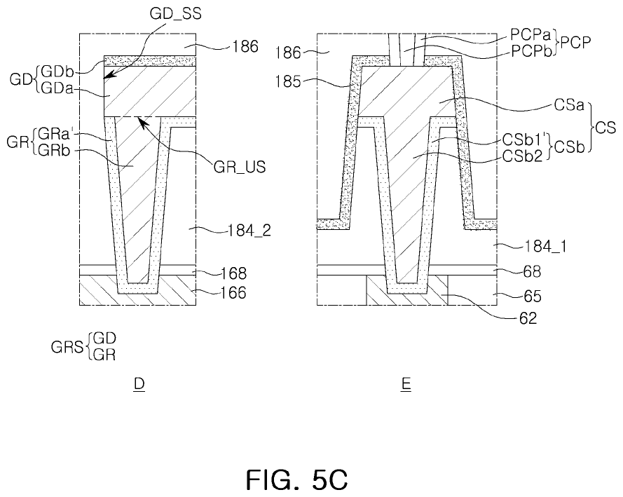

FIGS. 5A to 5C are enlarged diagrams illustrating a portion of a semiconductor device according to some example embodiments.

Referring to FIG. 5A, a semiconductor device 100A may be the same as or similar to the example described with reference to FIGS. 1 to 4, other than the configuration in which a horizontal width of the guard ring GR is smaller than a horizontal width of the contact plug CSb.

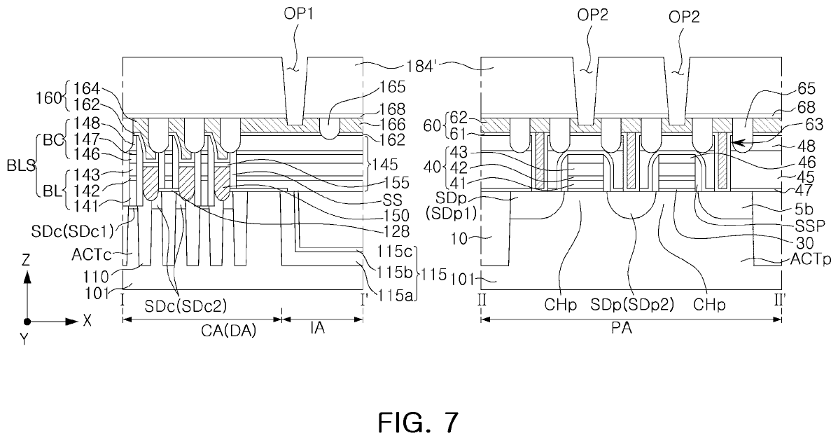

Referring to FIG. 7, a first horizontal width W1 of the first opening OP1 to form the guard ring GR surrounding the cell region CA may be smaller than a second horizontal width W2 of the second opening OP2 to form the contact plug CSb in the peripheral circuit region PA. Accordingly, an insulating film (or ‘barrier layer CSb1’) may be formed on a sidewall of the second opening OP2, and the second opening OP2 may be filled with a conductive material (or “conductive layer CSb2”), whereas an internal portion including a sidewall of first opening OP1 may be entirely filled with an insulating material. For example, an inside of guard ring GR and a sidewall of guard ring GR may include an insulating material (the inside of the guard ring GR is filled with the insulating material and the sidewall of the guard ring GR is covered by the insulating material).

Accordingly, the first pattern GDa of the dummy guard pattern GD and the first guard pattern GR may include different materials, such that a boundary surface between an upper region of the guard ring GR and a lower region of the dummy guard pattern GD may be distinct.

Referring to FIG. 5B, the semiconductor device 100B may be the same as or similar to the example described with reference to FIGS. 1 to 4, other than the configuration in which no liner pattern is present on a sidewall of each of the guard ring GR and the contact plug CSb.

Referring to FIG. 7, internal portions of the first opening OP1 and the second opening OP2 may be filled only with a conductive material. Accordingly, on a sidewall of guard ring GR, a liner pattern, which may be distinct from the lower interlayer insulating layer 186 disposed on one side of guard ring GR and the interlayer insulating pattern layer 184_2 disposed on the other side of guard ring GR, may not be present. Similarly, on the sidewall of the contact plug CSb, a liner pattern, which may be distinct from the interlayer insulating pattern layer 184_1 disposed on both sides of the contact plug CSb, may not be present.

Referring to FIG. 5C, the semiconductor device 100C may be the same as or similar to the example described with reference to FIGS. 1 to 4, other than the configuration in which barrier layers GRa′ and CSb1′ of a guard ring GR and a contact plug CSb are configured as conductive films including a conductive material.

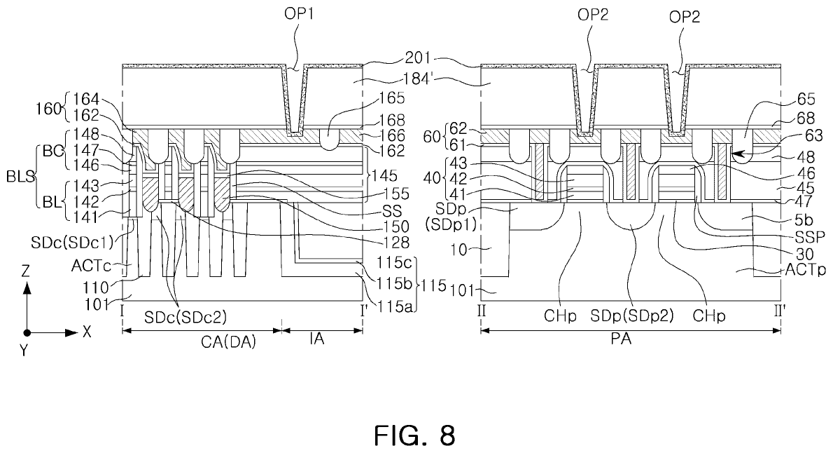

Referring to FIGS. 7 and 8 together, a conductive material may be formed on each of a sidewall and a lower surface of the first opening OP1 and the second opening OP2, and for example, an anisotropic etching process may not be performed subsequently.

Accordingly, referring back to FIG. 5C, the barrier layer GRa′ of the guard ring GR may be disposed on a sidewall and a lower surface of the guard ring GR, and may extend along a region between the first pattern GDa of the dummy guard pattern GD and the interlayer insulating pattern layer 184_2 in an upper region of the guard ring GR.

Similarly, the barrier layer CSb1 of the contact plug CSb may be disposed on a sidewall and a lower surface of the contact plug CSb, and may extend along a region between the pad pattern CSa and the interlayer insulating pattern layer 184_1 in an upper region of the contact plug CSb. Accordingly, at least a portion of the barrier layer CSb1′ may be in contact with at least a portion of the insulating liner 185 between the pad pattern CSa and the interlayer insulating pattern layer 184_1.

Each of the barrier layers GRa and CSb1 according to some example embodiments may be formed of a different material from that of each of the first pattern GDa and the pad pattern CSa of the dummy guard pattern, and even when the components include the same material, a boundary may be distinct by a difference in physical properties.

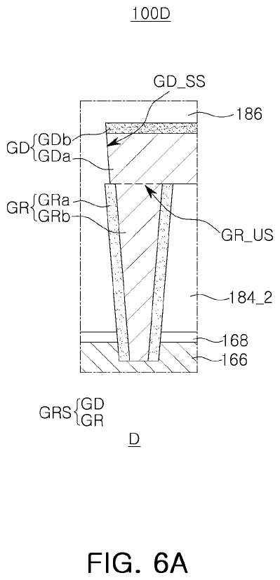

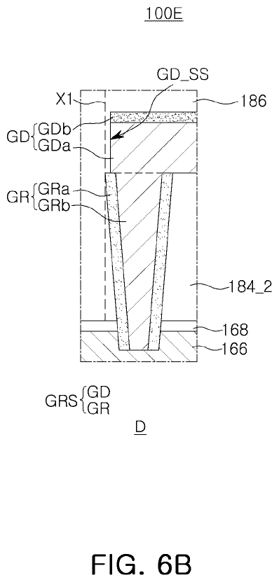

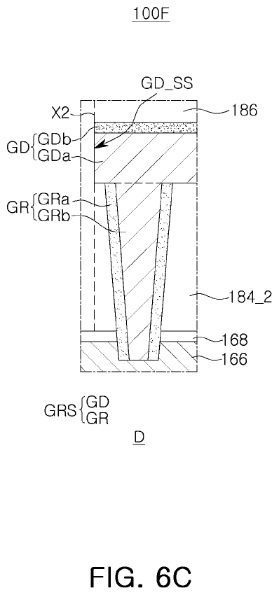

FIGS. 6A to 6C are enlarged diagrams illustrating a portion of a semiconductor device according to some example embodiments.

Referring to FIG. 6A, a semiconductor device 100D may be the same as or similar to the example described with reference to FIGS. 1 to 5C, other than the configuration in which a side surface GD_SS of the dummy guard pattern GD is inclined with respect to an upper surface GR_US of a guard ring GR.

Referring to FIG. 6A, the side surface GD_SS of the dummy guard pattern GD may be inclined toward the upper surface GR_US of the guard ring GR, and accordingly, at least a portion of the upper surface GR_US of the guard ring may be exposed, and may be in contact with the lower interlayer insulating layer 186. For example, the side surface GD_SS of the dummy guard pattern may be inclined toward the upper surface GR_US of the guard ring such that at least a portion of the upper surface of the barrier layer GRa of the guard ring GR may be exposed, but some example embodiments thereof are not limited thereto. For example, the side surface GD_SS of the dummy guard pattern may be inclined with respect to the upper surface GR_US of the guard ring such that at least a portion of an upper surface of the conductive layer GRb of the guard ring GR is exposed (not illustrated).

Referring to FIG. 6B, the semiconductor device 100E may be the same as or similar to the example described with reference to FIGS. 1 to 5C, other than the configuration in which a dummy guard pattern GD may be disposed farther from a cell array region CA than an upper region of a guard ring GR.

Referring to FIG. 6B, the side surface GD_SS of the dummy guard pattern may be disposed farther from the cell array region CA than one side surface of the upper region of the guard ring GR. For example, a conceptual line X1 extending in a vertical direction (Y-direction) from an edge of the upper region of the guard ring GR may be disposed closer to the cell array region CA than the side surface GD_SS of the dummy guard pattern.

Accordingly, at least a portion of an upper surface of the barrier layer GRa of the guard ring GR may be exposed. Although not illustrated, at least a portion of the upper surface of the conductive layer GRb of the guard ring GR may be exposed.

Referring to FIG. 6C, a semiconductor device 100F may be the same as or similar to the example described with reference to FIGS. 1 to 5C, other than the configuration in which the dummy guard pattern GD may be disposed closer to the cell array region CA than the upper region of the guard ring GR.

Referring to FIG. 6C, the side surface GD_SS of the dummy guard pattern may protrude in the horizontal direction toward the cell array region CA rather than one side surface of the upper region of the guard ring GR. Accordingly, the side surface GD_SS of the dummy guard pattern may be disposed closer to the cell array region CA than one side surface of the upper region of the guard ring GR. For example, a conceptual line X2 extending in the vertical direction (Y-direction) from the side surface GD_SS of the dummy guard pattern may be disposed closer to the cell array region CA than one side surface of the upper region of the guard ring GR.

FIGS. 7 to 15 are cross-sectional diagrams illustrating a method of manufacturing a semiconductor device according to some example embodiments.

Referring to FIG. 7, a preliminary interlayer insulating pattern layer 184′ may be formed on a lower structure including a substrate 101, a wordline, and a bitline structure BLS, and a plurality of openings OP1 and OP2 penetrating the preliminary interlayer insulating pattern layer 184′ may be formed.

A preliminary interlayer insulating pattern layer 184′ may be formed on the etch stop layers 68 and 168 conformally formed on the lower structure.

A photomask may be aligned on the preliminary interlayer insulating pattern layer 184′, and a first opening OP1 penetrating at least a portion of the dummy conductive pattern 166, the preliminary interlayer insulating pattern layer 184′ and the etch stop layer 168 may be formed to expose at least a portion of the dummy conductive pattern 166 on the interface region IA (see FIG. 1).

A second opening OP2 penetrating at least a portion of the peripheral interconnections 62, the preliminary interlayer insulating pattern layer 184′ and the etch stop layer 68 may be formed such that at least a portion of the peripheral interconnections 62 may be exposed on the peripheral circuit region PA.

Referring to FIG. 8, a preliminary barrier layer 201 conformally covering an internal surface of the plurality of openings OP1 and OP2 and an upper surface of the preliminary interlayer insulating pattern layer 184′ may be formed.

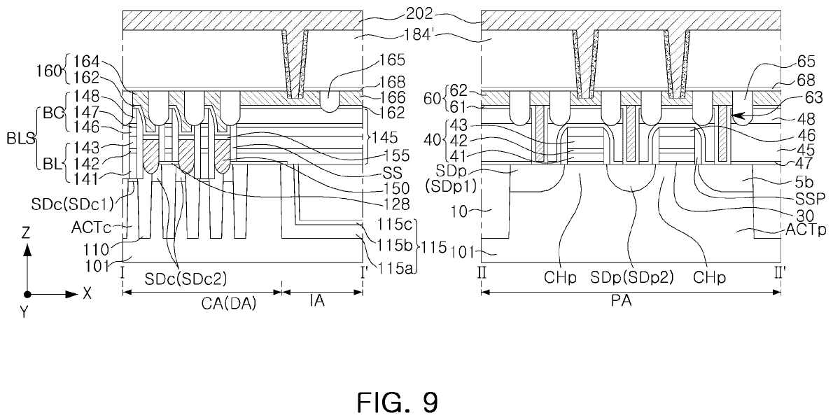

The preliminary barrier layer 201 may include an insulating material or a conductive material. When the preliminary barrier layer 201 includes an insulating material, at least a portion of the preliminary barrier layer 201 formed in the plurality of the openings OP1 and OP2 may be etched and removed (see FIGS. 4 and 9). Differently from the above example, when the preliminary barrier layer 201 includes a conductive material, the preliminary barrier layer 201 formed in the plurality of openings OP1 and OP2 may not be removed (see FIG. 5C).

Referring to FIG. 9, at least a portion of the preliminary barrier layer 201 may be removed by an etching process, and a preliminary conductive layer 202 filling the plurality of openings OP1 and OP2 and covering an upper surface of the preliminary interlayer insulating pattern layer 184′ may be formed.

The preliminary barrier layer 201 formed on a lower surface of the plurality of openings OP1 and OP2 and an upper surface of the preliminary interlayer insulating pattern layer 184′ may be removed through anisotropic etching. Accordingly, at least a portion of the dummy conductive pattern 166 and at least a portion of the peripheral interconnections 62 may be exposed in the vertical direction (Z-direction).

Thereafter, a preliminary conductive layer 202 filling the plurality of openings OP1 and OP2 and covering the upper surface of the preliminary interlayer insulating pattern layer 184′ may be formed.

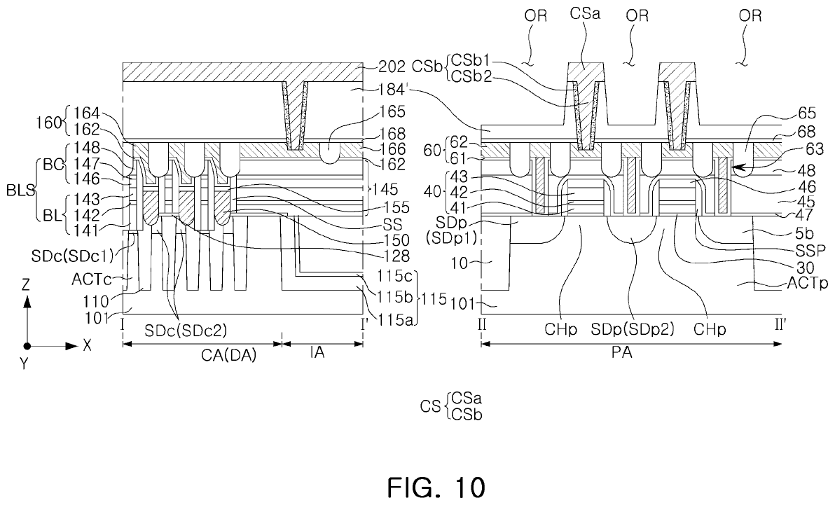

Referring to FIG. 10, in the peripheral circuit region PA, a plurality of open regions OR penetrating at least a portion of the preliminary conductive layer 202 and the preliminary interlayer insulating pattern layer 184′ may be formed.

The plurality of open regions OR may be formed by aligning a photomask on the preliminary conductive layer 202 and using a photo lithography process. A connection structure CS including the pad pattern CSa and the contact plug CSb may be defined by the plurality of open regions OR.

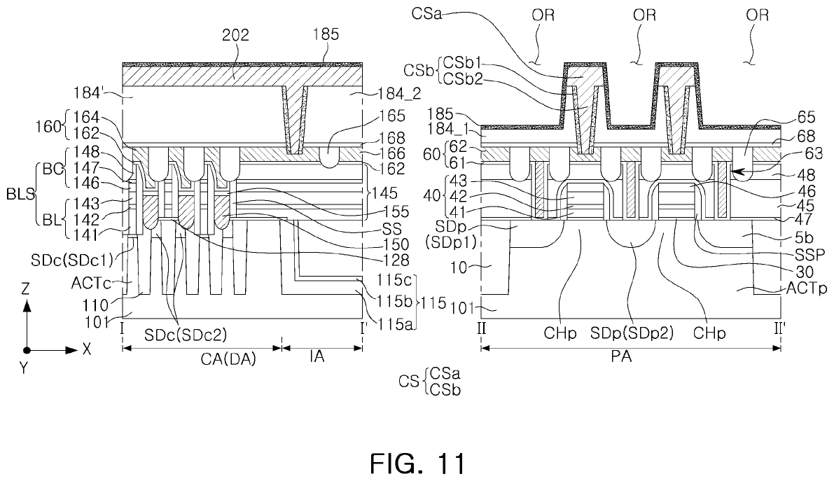

Referring to FIG. 11, after the process in FIG. 10, an insulating liner 185 may be formed.

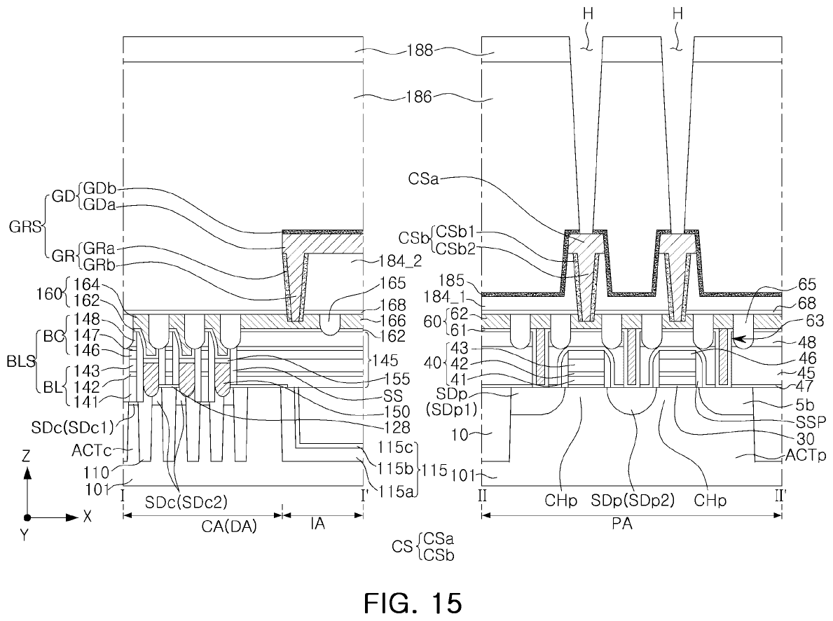

Referring to FIG. 15 together, the insulating liner 185 may be a stopper layer for forming a peripheral contact plug hole H on the connection structure CS.

The insulating liner 185 may be formed on the preliminary conductive layer 202 in the cell region CA and the interface region IA, and may be formed conformally along a surface of the plurality of open regions OR in the peripheral circuit region PA.

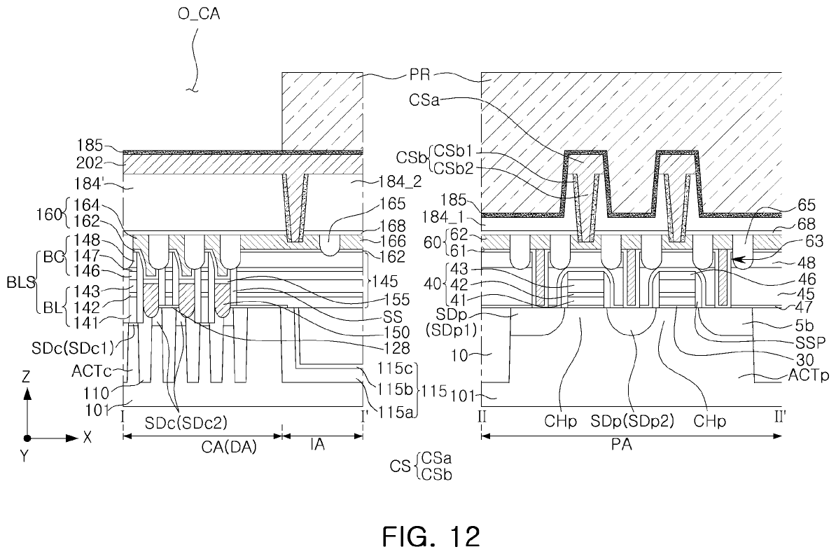

Referring to FIG. 12, after the process in FIG. 11, a photoresist layer PR may be formed across a cell region CA, an interface region IA, and a peripheral circuit region PA, and the photoresist layer PR on the cell region CA may be removed such that the cell open region O_CA may be formed.

The cell open region O_CA may be formed by aligning a photomask on the photoresist layer PR and using a photo lithography process. The cell open region O_CA may be formed by removing the photoresist layer PR on the cell region CA, and accordingly, the insulating liner 185 on the cell region CA may be exposed.

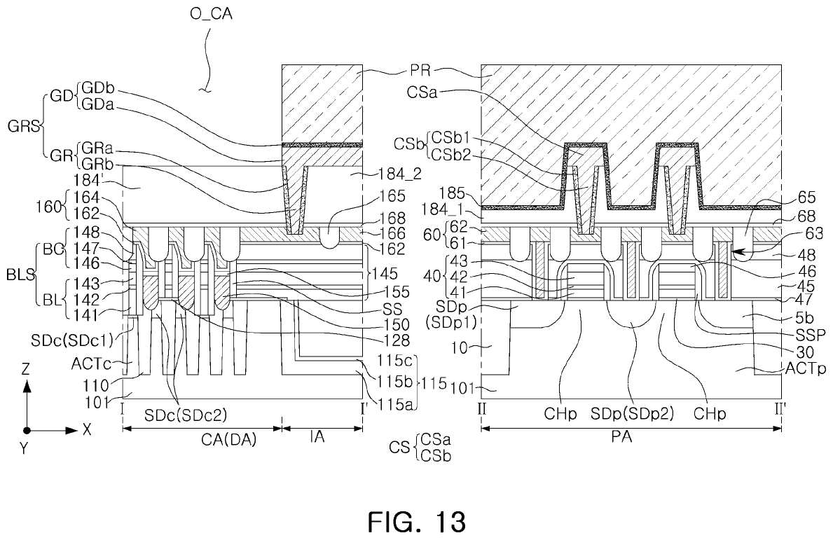

Referring to FIG. 13, the insulating liner 185 and the preliminary conductive layer 202 on the cell region CA may be removed by an etching process.

Through the etching process, a guard ring structure GRS including a guard ring GR and a dummy guard pattern GD may be defined. A side surface GD_SS (e.g., see FIG. 5A) of the dummy guard pattern may be formed to be substantially coplanar with a side surface of the photoresist layer PR defined by the cell open region O_CA.

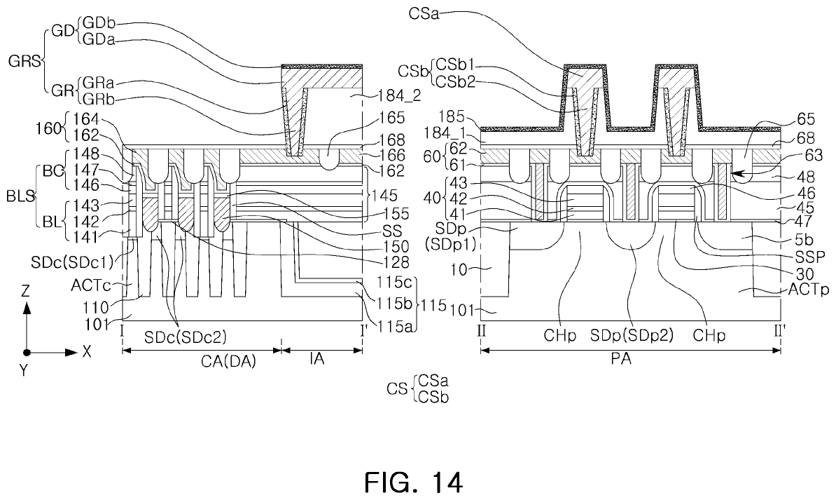

Referring to FIG. 14, after the process in FIG. 13, the preliminary interlayer insulating pattern layer 184′ on the cell region CA may be removed by an etching process.

The etch stop layer 168 may not be etched by the etching process mentioned above, and may maintain a conformal thickness on the same level throughout the cell region CA and the peripheral circuit region PA.

Referring to FIG. 15, after the process in FIG. 14, at least one of interlayer insulating layers 186 and 188 and a contact plug hole H penetrating at least a portion of the interlayer insulating layer 186 and 188 may be formed on the peripheral circuit region PA.

The contact plug hole H may be formed to penetrate at least a portion of the interlayer insulating layers 186 and 188 and to penetrate the insulating liner 185 on the connection structure CS. Thereafter, a barrier layer PCPa may be formed on an internal sidewall of the contact plug hole H, and a peripheral contact plug PCP may be formed by forming a conductive layer PCPb on the barrier layer PCPa (see FIG. 4).

Although not illustrated, before forming the peripheral contact plug PCP on the peripheral circuit region PA, the data storage structure CAP may be preferentially formed on the cell region CA (see FIG. 3B). For example, before forming the interlayer insulating layers 186 and 188, a desired (and/or alternatively predetermined) mold structure may be formed throughout the cell region CA and the peripheral circuit region PA. The desired (and/or alternatively predetermined) mold structure may be formed on a lower structure including the substrate 101, a wordline, a bitline structure BLS, the guard ring structure GRS, and the connection structure CS. The desired (and/or alternatively predetermined) mold structure may be formed by alternately stacking a plurality of mold layers and a plurality of preliminary supporter patterns on the etch stop layer 168. Thereafter, a plurality of openings penetrating the desired (and/or alternatively predetermined) mold structure may be formed, and the first electrode structures 170 may be formed in the plurality of openings. Thereafter, the plurality of mold layers may be removed, and a dielectric layer 172 covering surfaces of the plurality of preliminary supporter patterns and the first electrode structures 170 may be formed, and the second electrode structures 174 may be formed.

Thereafter, a cell contact plug CCP connected to the data storage structure CAP may be formed, wherein the cell contact plug CCP may be formed together with the peripheral contact plug PCP according to FIG. 15. Subsequently, the interlayer insulating layer ILD and the plurality of upper contact plugs 92 and 95 may be formed.

According to the aforementioned example embodiments, a semiconductor device having improved reliability may be provided.

While some example embodiments have been illustrated and described above, it will be apparent to those skilled in the art that modifications and variations may be made without departing from the scope of the inventive concepts as defined by the appended claims.

What is claimed is:

1. A semiconductor device, comprising:
a substrate including a cell array region and a peripheral circuit region;
a peripheral gate structure on the peripheral circuit region of the substrate, the peripheral gate structure including a peripheral gate dielectric layer, a peripheral gate electrode on the peripheral gate dielectric layer, peripheral source/drains on both sides of the peripheral gate electrode, and a peripheral gate capping pattern on the peripheral gate electrode;
a first peripheral interlayer insulating layer having at least a portion on a side surface of the peripheral gate structure;
peripheral interconnections on the first peripheral interlayer insulating layer and the peripheral gate structure;
an insulating pattern layer on the peripheral interconnections;
a connection structure including a pad pattern and a first peripheral contact plug, the pad pattern being on the insulating pattern layer, and the first peripheral contact plug penetrating the insulating pattern layer and electrically connecting the pad pattern to a peripheral interconnection from among the peripheral interconnections; and
a guard ring structure including a guard ring, the guard ring structure surrounding the cell array region between the cell array region and the peripheral circuit region of the substrate,
wherein at least a portion of the guard ring of the guard ring structure is at a same level as at least a portion of the first peripheral contact plug of the connection structure.

2. The semiconductor device of claim 1, further comprising:
a wordline, a bitline, and a data storage structure on the cell array region of the substrate,
wherein the wordline and the bitline are at a level lower than a level of the guard ring,
wherein the data storage structure includes a first electrode structure, a second electrode structure and a dielectric layer between the first electrode structure and the second electrode structure, and
wherein at least one of the first and second electrode structures comprises a lower surface at a level lower than a level of an upper surface of the guard ring, and an upper surface at a level higher than the level of the upper surface of the guard ring.

3. The semiconductor device of claim 1, further comprising:
a dummy conductive pattern extending from the cell array region of the substrate to the peripheral circuit region, and
wherein a lower region of the guard ring of the guard ring structure penetrates at least a portion of the dummy conductive pattern.

4. The semiconductor device of claim 1, wherein an upper surface of the guard ring of the guard ring structure is at a same level as an upper surface of the first peripheral contact plug of the connection structure.

5. The semiconductor device of claim 1, wherein each of the guard ring and the first peripheral contact plug includes a conductive layer, and an insulating layer on a side surface of the conductive layer.

6. The semiconductor device of claim 5, wherein the insulating layer includes at least one of silicon oxycarbide, silicon nitride, and silicon oxycarbonitride.

7. The semiconductor device of claim 1,
wherein a horizontal width of the guard ring is smaller than a horizontal width of the first peripheral contact plug,
wherein an inside of the guard ring and a sidewall of the guard ring include an insulating material, and
wherein the first peripheral contact plug includes a conductive layer and an insulating layer on a side surface of the conductive layer.

8. The semiconductor device of claim 1, wherein each of the guard ring, a sidewall of the guard ring, the first peripheral contact plug and a sidewall of the first peripheral contact plug include a conductive material.

9. The semiconductor device of claim 1, further comprising:
an interlayer insulating pattern extending in a horizontal direction from one side of the guard ring toward the peripheral circuit region,
wherein the guard ring structure further includes a dummy guard pattern on the guard ring and the interlayer insulating pattern,
wherein the guard ring includes a first conductive layer and a second conductive layer on the first conductive layer, and
wherein the second conductive layer extends along a region between the interlayer insulating pattern and the dummy guard pattern.

10. The semiconductor device of claim 9,
wherein the first peripheral contact plug includes a third conductive layer and a fourth conductive layer on the third conductive layer, and
wherein the fourth conductive layer extends along a region between the insulating pattern layer and the pad pattern.

11. The semiconductor device of claim 10, wherein the second and fourth conductive layers include a same conductive material.

12. The semiconductor device of claim 11, wherein the conductive material includes at least one of metal nitride and tungsten.

13. A semiconductor device, comprising:
a substrate including a cell array region and a peripheral circuit region;
a conductive region in the cell array region;
a peripheral gate structure on the peripheral circuit region of the substrate, the peripheral gate structure including a peripheral gate dielectric layer, a peripheral gate electrode on the peripheral gate dielectric layer, peripheral source/drains on both sides of the peripheral gate electrode, and a peripheral gate capping pattern on the peripheral gate electrode;
a first peripheral interlayer insulating layer having at least a portion on a side surface of the peripheral gate structure;
peripheral interconnections on the first peripheral interlayer insulating layer and the peripheral gate structure;
an insulating pattern layer on the peripheral interconnections;
a stopper layer on the conductive region on the cell array region, and the stopper layer being between the peripheral interconnections and the insulating pattern layer on the peripheral circuit region;
a guard ring structure including a guard ring, the guard ring surrounding the cell array region, and the guard ring having a lower region penetrating the stopper layer at a portion of the stopper layer between the cell array region and the peripheral circuit region of the substrate; and
a connection structure on the peripheral circuit region of the substrate, the connection structure including a pad pattern and a first peripheral contact plug, the pad pattern being on the insulating pattern layer, and the first peripheral contact plug penetrating the insulating pattern layer and the stopper layer and electrically connecting the pad pattern to a peripheral interconnection from among the peripheral interconnections.

14. The semiconductor device of claim 13, wherein the guard ring structure further includes a dummy guard pattern on the guard ring, and the dummy guard pattern extending in a horizontal direction toward the peripheral circuit region.

15. The semiconductor device of claim 14,
wherein in cross-sectional view, a side surface of the dummy guard pattern is inclined with respect to an upper surface of the guard ring, and
wherein at least a portion of the upper surface of the guard ring is exposed by the dummy guard pattern.

16. The semiconductor device of claim 14,
wherein in cross-sectional view, one side surface of an upper region of the guard ring is closer to the cell array region than one side surface of the dummy guard pattern, and
wherein at least a portion of an upper surface of the guard ring is exposed by the dummy guard pattern.

17. The semiconductor device of claim 14, wherein in cross-sectional view, one side surface of the dummy guard pattern protrudes further in the horizontal direction toward the cell array region than one side surface of an upper region of the guard ring.

18. The semiconductor device of claim 14,
wherein the dummy guard pattern includes a first pattern on the guard ring and a second pattern on the first pattern,
wherein the second pattern extends to the peripheral circuit region, and
wherein the second pattern covers at least a portion of a surface of the insulating pattern layer and a surface of the pad pattern of the connection structure.

19. The semiconductor device of claim 18, wherein the first pattern of the dummy guard pattern and the pad pattern of the connection structure include a same material.

20. A semiconductor device, comprising:
a substrate including a cell array region and a peripheral circuit region;
a memory structure including a wordline, a bitline, and a data storage structure on the cell array region;
a peripheral gate structure on the peripheral circuit region of the substrate, the peripheral gate structure including a peripheral gate dielectric layer, a peripheral gate electrode on the peripheral gate dielectric layer, peripheral source/drains on both sides of the peripheral gate electrode, and a peripheral gate capping pattern on the peripheral gate electrode;
a first peripheral interlayer insulating layer having at least a portion on a side surface of the peripheral gate structure;
peripheral interconnections on the first peripheral interlayer insulating layer and the peripheral gate structure;
an insulating pattern layer on the peripheral interconnections;
a pad pattern on the insulating pattern layer;
a first peripheral contact plug penetrating the insulating pattern layer and electrically connecting the pad pattern to a peripheral interconnection from among the peripheral interconnections;
an insulating liner covering the insulating pattern layer and the pad pattern;
a second peripheral interlayer insulating layer on the insulating liner;
a second peripheral contact plug penetrating the second peripheral interlayer insulating layer and the insulating liner, the second peripheral contact plug being electrically connected to the pad pattern;
a guard ring surrounding the cell array region between the cell array region and the peripheral circuit region of the substrate; and
a dummy guard pattern on the guard ring and extending in a horizontal direction toward the peripheral circuit region,
wherein the wordline and the bitline are at a level lower than a level of the guard ring,
wherein the data storage structure includes a first electrode structure, a second electrode structure and a dielectric layer between the first electrode structure and the second electrode structure, and
wherein at least one of the first and second electrode structures comprises a lower surface at a level lower than a level of an upper surface of the guard ring, and an upper surface at a level higher than the level of the upper surface of the guard ring.
